(19) United States
(12) Patent Application Publication
(10) Pub. No.: US 2011/0254053 A1
(43) Pub. Date: Oct. 20, 2011

(54) SUPERCONDUCTOR TRANSISTOR AND METHOD FOR MANUFACTURING SUCH TRANSISTOR

(75) Inventors: Christophe Goupil, Caen (FR); Alain Pautrat, Caen (FR); Charles Simon, St. Vigord Le Grand (FR); Patrice Mathieu, La Varenne St-Hilaire (FR)

(73) Assignees: Ensicaen, Caen Cedex (FR); Centre National De La Recherche Scientifique (C.N.R.S.), Paris (FR)

(21) Appl. No.: 12/995,781

(22) PCT Filed: May 29, 2009
(86) PCT No.: PCT/FR2009/051010

§ 371 Date: Jul. 6, 2011

(30) Foreign Application Priority Data
Jun. 2, 2008 (FR) 0853620

(51) Int. Cl. H01L 39/14; H01L 21/335

(52) U.S. Cl. 257/192; 438/2; 257/E39.02; 257/E21.4

(57) ABSTRACT

This field-effect superconductor transistor (2) comprises a source electrode (4) and a drain electrode (6), connected by a superconducting channel (12), the channel (12) and the source (4) and drain (6) electrodes being arranged on a substrate (16), and a gate electrode (8) covering the channel (12).

A layer (14) of semiconductor material is arranged between the channel (12) and the gate electrode (8), to control over the critical current of the superconducting channel (12) between a minimum value Ic_min and a maximum value Ic_max, by controlling the surface roughness of said channel (12), said surface roughness being controlled by combining the proximity effect between the superconducting channel (12) and the layer (14) of semiconductor material with the field effect in the layer (14) of semiconductor material by polarising the gate electrode (8).

The present invention concerns a field-effect superconductor transistor comprising a source electrode and a drain electrode, connected by a superconducting channel, the channel and the source and drain electrodes being arranged on a substrate, and a gate electrode covering the channel.

The invention also concerns a method for manufacturing a field-effect superconductor transistor, said transistor comprising a source electrode and a drain electrode connected by a superconducting channel, the channel and the source and drain electrodes being arranged on a substrate, and a gate electrode covering the channel.

The invention applies to any electronic component comprising at least one transistor, and notably power components such as current limiters or strong current switches.

Patent EP 0 505 259 describes a field-effect superconductor transistor comprising a substrate and a multilayer structure defining a channel that is arranged on the substrate. The transistor comprises a source electrode and a drain electrode connected by the channel. The channel is controlled by a gate electrode, between a blocking state in which the current substantially does not circulate between the source electrode and the drain electrode, and a conducting state in which the current circulates from the source electrode to the drain electrode. The amount of current circulating in the channel in the conducting state notably depends on the polarisation of the gate electrode. When the channel is blocked, the transistor is said to be in off-state, and when the channel allows current to pass, the transistor is said to be in on-state. The multilayer structure comprises at least one pair of layers formed of a superconducting layer and a non-superconducting layer.

However, the field effect, produced by polarising the gate electrode, directly affects the carrier rate in the superconducting channel. The maximum current density of the channel on this account is greatly limited. The field-effect superconductor transistor in the state of the art therefore only allows control over low currents.

Additionally, the current gain of the prior art transistor is frequently low.

The object of the invention is therefore to allow control over strong currents and to increase the current gain between the source electrode and the drain electrode when the transistor is in the on-state.

To this end, the subject-matter of the invention is a transistor of the aforementioned type, characterized in that a layer of semiconductor material is arranged between the channel and the gate electrode, to allow control over the critical current of the superconducting channel by controlling the surface roughness of said channel, said surface roughness being controlled through combination of the proximity effect between the superconducting channel and the layer of semiconductor material, and the field effect in the layer of semiconductor material, by polarising the gate electrode, said critical current being controlled between a minimum value Ic_min by reducing surface roughness under the effect of an accumulation of semiconductor free carriers at the interface between the semiconductor layer and the channel with a first polarisation voltage of the gate electrode, and a maximum value Ic_max by increasing the surface roughness under the effect of depletion of semiconductor free carriers at the interface between the semiconductor layer and the channel with a second polarisation voltage of the gate electrode.

According to other embodiments, the transistor comprises one or more of the following characteristics, taken alone or in any technically possible combination:
the gate electrode is galvanically insulated from the channel by an insulating layer arranged on the layer of semiconductor material, and the transistor is a MOSFET transistor,
the transistor is a JFET transistor,
the substrate is a semiconductor substrate,
the substrate is an amorphous substrate of glass or quartz type,
the substrate is a metal substrate,
the substrate is a flexible substrate of polymer type,
the superconducting channel is in a material in the group consisting of: niobium, aluminium, lead-indium, niobium-titanium, niobium-tin and magnesium diboride,
the critical current is determined by the width of the superconducting channel and the maximum value Ic_max is equal to or greater than 50 A/cm,
the critical current is determined by the width of the superconducting channel, and the minimum value Ic_min is between 0 A/cm and 0.5 A/cm,
the thickness of the superconducting channel is between 3 nm and 1 cm,
the source and drain electrodes are in superconducting material,
the channel is a finned channel.

A further subject of the invention is a manufacturing method of the aforementioned type, characterized in that it comprises the adding of a layer of semiconductor material between the channel and the gate electrode, so as to allow control over the critical current of the superconducting channel by controlling the surface roughness of said channel, said surface roughness being controlled by combining the proximity effect between the superconducting channel and the layer of semiconductor material with the field effect in the layer of semiconductor material, by polarising the gate electrode between a minimum value Ic_min by reducing the surface roughness under the effect of an accumulation of semiconductor free carriers at the interface between the semiconductor layer and the channel, and a maximum value Ic_max by increasing the surface roughness under the effect of depletion of semiconductor free carriers at the interface between the semiconductor layer and the channel.

According to other embodiments, the manufacturing method comprises one or more of the following characteristics taken alone or any technically possible combination:
the method comprises adding an insulating layer between the gate electrode and the layer of semiconductor material,
the thickness of the superconducting channel is between 3 nm and 1 cm,
the method comprises forming the substrate in a semiconductor material,
the method comprises forming the substrate in an amorphous material of glass or quartz type,
the method comprises forming the substrate in a metal or metal alloy,
the method comprises forming the substrate in a flexible material of polymer type,
the method comprises choosing the material of the superconducting channel in the group consisting of: niobium, aluminium, lead-indium, niobium-titanium, niobium-tin and magnesium diboride,
the method comprises creating the channel in the form of a finned channel.

The invention and its advantages will be better understood on reading the following description given solely as an example with reference to the appended drawings in which:

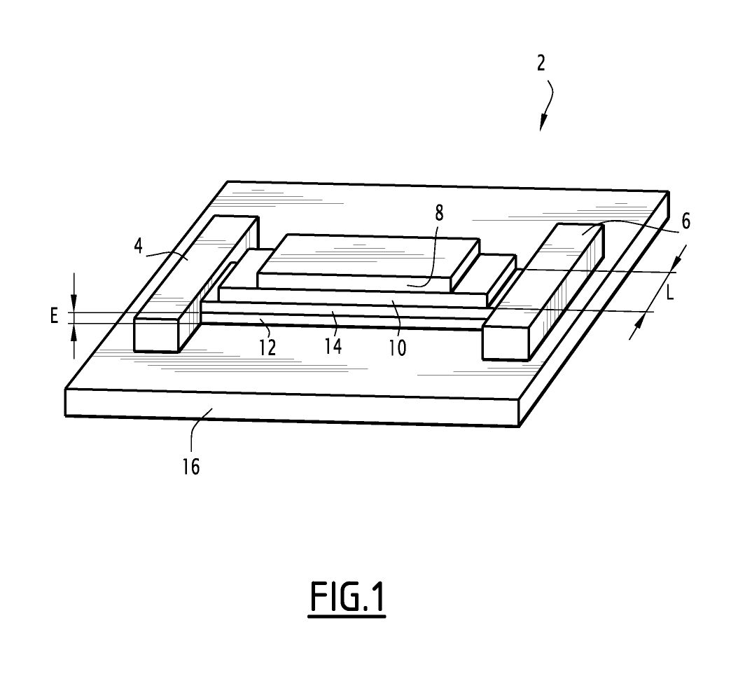

FIG. 1 is a schematic illustration of the field-effect superconductor transistor according to a first embodiment of the invention,

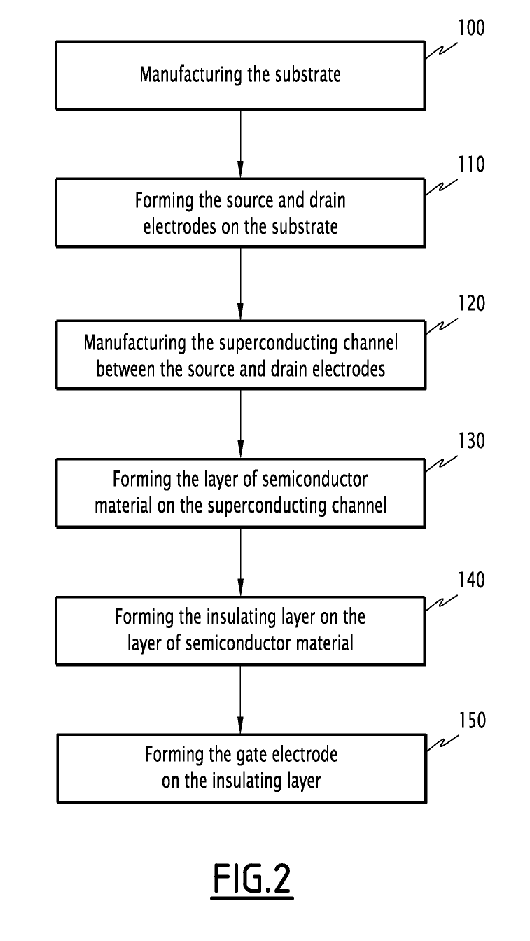

FIG. 2 is a flow chart of operations for the manufacturing method according to the first embodiment of the invention,

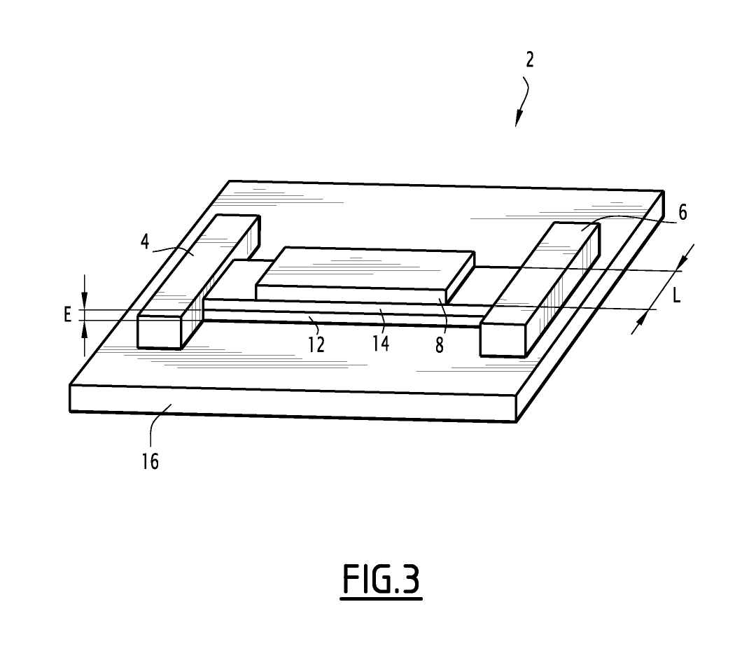

FIG. 3 is a schematic illustration of the field-effect superconductor transistor according to a second embodiment of the invention, and

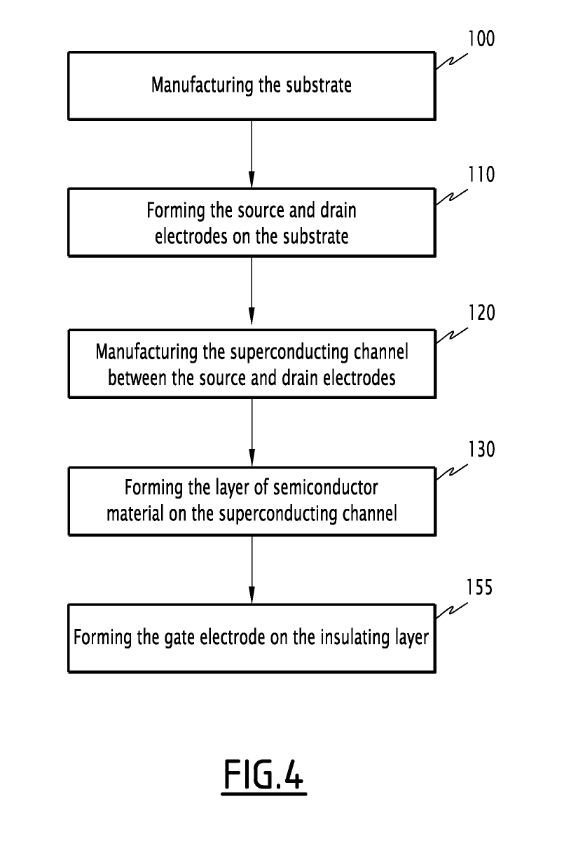

FIG. 4 is a flow chart of operations for the manufacturing method according to the second embodiment of the invention.

In FIG. 1, a field-effect superconductor transistor 2 comprises a source electrode 4, a drain electrode 6 and a gate electrode 8. The gate electrode 8 is electrically insulated from the remainder of the transistor by a gate insulating layer 10. The source 4 and drain 6 electrodes are connected by a superconducting channel 12.

In the described embodiment, the transistor 2 is of MOSFET type (Metal-Oxide Semiconductor Field-Effect Transistor).

A layer of semiconductor material 14 is arranged between the channel 12 and the insulating layer 10 of the gate electrode. The source electrode 4, the drain electrode 6 and the superconducting channel 12 are arranged on a substrate 16.

The ratios of the dimensions shown in FIG. 1 have been deliberately modified for clarity of the drawings.

In the described embodiment, the source 4, drain 6 and gate 8 electrodes are in metal. The gate electrode 8 is in aluminium or tungsten for example. The source 4 and drain 6 electrodes are in aluminium or tungsten for example. The insulating layer 10 is manufactured in a thermal oxide, e.g. silicon dioxide (SIO₂).

The superconducting channel 12 extends between the source electrode 4 and the drain electrode 6 in a longitudinal direction. The channel 12 has a width L in a transverse direction perpendicular to the longitudinal direction. The width L of the channel 12 is between 10 nanometres and 0.1 micrometre, and preferably equal to 100 nanometres. The channel 12 is of thickness E, as can be seen on FIG. 1, of between 3 nanometres and one centimetre, and is preferably equal to 0.1 micrometre.

The superconducting material of the channel 12 is a type II superconducting material e.g. niobium (Nb).

The surface of the channel 12 in contact with the layer of semiconductor material 14 is called the upper surface of the superconducting channel 12, and the surface in contact with the substrate 16 is called the lower surface of the superconducting channel 12.

The layer of semiconductor material 14 is capable of allowing control over the critical current Ic of the superconducting channel 12 between a minimum value Ic_min and a maximum value Ic_max by controlling the surface roughness of the channel 12. The surface roughness is controlled by combining the proximity effect between the superconducting channel 12 and the layer of semiconductor material 14 with the field effect in the layer 14 of semiconductor material, by polarising the gate electrode 8.

The critical current Ic is determined by the width L of the superconducting channel 12. The maximum value Ic_max of the critical current is equal to or greater than 50 amperes per centimetre.

The minimum value Ic_min lies between 0 Ampere per centimetre and 0.5 ampere per centimetre, and is preferably 0.1 ampere per centimetre.

In the described embodiment, the substrate 16 is formed in a semiconductor material, such as bulk silicon.

The method for manufacturing the superconductor transistor 2 will now be described with reference to FIG. 2.

The manufacturing method starts with step 100 to form the semiconductor substrate 16.

The method continues with step 110 to form the source 4 and drain 6 metal electrodes on the semiconductor substrate 16.

The superconducting channel 12 is then formed at step 120, by depositing niobium between the source 4 and drain 6 electrodes, over a width L, until a thickness E is obtained.

After forming the superconducting channel 12 the method, at step 130, comprises adding the layer 14 of semiconductor material on the superconducting channel 12, so as to allow control over the critical current Ic of the superconducting channel 12 by controlling the surface roughness of the channel 12.

In the described embodiment, the manufacturing method is continued by step 140 to form the insulating layer 10 on the layer of semiconductor material 14.

The manufacturing method is completed at step 150 by forming the gate electrode 8 in tungsten on the insulating layer 10 in silicon dioxide.

The operating principle of the superconductor transistor 2 lies in the control over the electric resistance of the channel 12 under the effect of polarising the gate electrode 8.

The value of the electric resistance of the channel 12 is substantially zero if the superconducting channel 12 is in a non-dissipating superconducting state, or on-state. On the contrary, if the superconducting channel 12 is in a dissipating state or off-state, then the electric resistance of the channel is non-zero. The result is switching behaviour of the transistor 2 between the superconducting or non-dissipating state and the dissipating state. This switching behaviour does not exclude a linear mode in which the channel resistance varies proportionally under the effect of polarising the gate electrode 8.

The conduction of the channel 12 is controlled by the polarisation voltage V_{GS} applied between the gate electrode 8 and the source electrode 4.

For reasons of simplification, the polarisation voltage V_{GS} applied between the gate electrode 8 and the source electrode 4 is called the polarisation voltage Vg of the gate electrode 8.

With a first value of the polarisation voltage Vg of the gate electrode 8, the free carriers of the semiconductor material of layer 14 accumulate at the interface between the layer of semiconductor material 14 and the superconducting channel 12, the effect of which is to reduce surface roughness via a proximity effect. The minimum value Ic_min of the critical current Ic is obtained with minimum roughness of the upper surface of the superconducting channel 12.

With a second value of the polarisation voltage Vg of the gate electrode 8, the free carriers of the semiconductor material of layer 14 are depleted at the interface between the layer of semiconductor material 14 and the superconducting channel 12, the effect of which is to increase surface roughness via a proximity effect. The maximum value Ic_max of the critical current Ic is obtained with maximum roughness of the upper surface of the superconducting channel 12.

The surface roughness of the superconducting channel 12 effectively contributes towards anchoring the vortices, by providing connecting sites for non-normal vortices at the mean surface. Since the vortices are anchored, they do not perturb the superconducting state of the channel 12, which always substantially acts as a perfect conductor, which corresponds to a strong critical current.

Conversely, movement of the vortex lattice is not constrained when the surface of the channel 12 is scarcely rough, even smooth. The movement of the vortex lattice then sets up an electromotive force, since each vortex carries a magnetic flux, and the superconducting channel 12 no longer acts as a perfect conductor, which corresponds to a low critical current.

Therefore, a sample with high roughness shows a strong critical current, and conversely a sample with low roughness shows a low critical current. The critical current is substantially zero with a substantially smooth surface.

This relationship between surface roughness and critical current is well known to the person skilled in the art, and is described for example in the publication <<Quantitative analysis of the critical current due to vortex pinning by surface corrugation>> by Pautrat, Scola, Goupil et al., published in Physical Review, B69, article n^{o} 224504, June 2004.

Under the action of the polarisation voltage Vg of the gate electrode 8, the superconductor transistor 2 provides control over the anchoring and de-anchoring of vortices, and hence control over the onset threshold value of nonzero electric resistance of the superconducting channel 12.

The so-called proximity effect characterizes the fact that a layer of highly doped semiconductor material, deposited on a superconducting layer, itself becomes superconducting on a film whose thickness is related to free carrier mobility and concentration. This effect is well known to a skilled person and is described for example in the publication <<Boundary effects in superconductors>> by Pierre-Gilles de Gennes, published in Reviews of Modern Physics, January 1964.

If the polarisation voltage Vg of the gate electrode 8 leads to increasing the free carrier concentration in the vicinity of the interface between the superconducting channel 12 and the semiconductor layer 14, then the roughness is smoothed and the critical current Ic is reduced down to a minimum value Ic_min. If the value of the critical current Ic is close to the minimum value Ic_min, the superconductor transistor 2 is in the off-state.

If, on the contrary, the polarisation voltage Vg of the gate electrode 8 leads to depleting the interface between the superconducting channel 12 and the semiconductor layer 14, then the surface roughness increases, involving an increase in the critical current Ic up to a maximum value Ic_max. If the value of the critical current Ic is close to the maximum value Ic_max, the superconducting transistor 2 is in the on-state.

The interface between the semiconductor layer 14 and the superconducting channel 12 therefore behaves as a surface with variable roughness in relation to the polarisation voltage Vg of the gate electrode 8.

If the superconductor transistor 2 is in the on-state, the current circulates from the source electrode 4 to the drain electrode 6 both in the superconducting channel 12 and in the thickness of the layer 14 of semiconductor material where the free carriers are located. This thickness of the layer 14 of semiconductor material then becomes superconducting via a proximity effect.

The transistor 2 of the invention therefore allows direct control, through an electrostatic field effect, over the critical current Ic of the superconducting channel 12.

Advantageously, the superconductor transistor 2 of the invention is able to be used for applications concerning strong currents such as power switching and current limitation. The dissipating state of the superconducting channel 12 effectively does not result from a reduction in the carrier rate but from reduction of the critical current Ic by the de-anchoring of vortices.

Advantageously, the superconductor transistor 2 of the invention allows the controlling of a current of intensity equal to or greater than 50 amperes for each centimetre of width L of the superconducting channel 12.

Advantageously, the current gain of the transistor 2 is substantial.

Advantageously, the superconductor transistor 2 of the invention can be used for applications concerning low currents.

Advantageously, the frequency response of the superconductor transistor 2 according to the invention is high, since the transition between the dissipating state of the channel 12 and the superconducting or non-dissipating state is due to vortex dynamics.

Advantageously, the method of the invention for manufacturing the superconductor transistor 2 does not require any heavy technological means allowing depositing or etching on nanometre scale.

Advantageously, the manufacturing method of the invention does not require a superconducting channel of very narrow thickness. The layer which undergoes the field effect due to polarisation of the gate electrode 8 is effectively not the superconducting channel 12 itself, but solely the semiconductor layer 14 deposited on the channel 12.

FIGS. 3 and 4 illustrate a second embodiment of the invention, in which elements that are similar to those in the embodiment previously described are designated with identical references.

According to the second embodiment, the field-effect superconductor transistor 2 does not comprise any insulating layer between the gate electrode 8 and the layer of semiconductor material 14, as illustrated FIG. 3.

In this second embodiment, the transistor 2 is of JFET type (Junction Field Effect Transistor) in which the gate electrode 8 is directly in contact with the channel 12.

In FIG. 4, the method for manufacturing the transistor 2 according to the second embodiment does not comprise a step to form an insulating layer on the layer of semiconductor material 14.

Step 155, the last step in the manufacturing method, comprises the forming of the gate electrode 8 directly on the layer of semiconductor material 14.

The conducting of this second embodiment is identical to the conducting of the first embodiment and is therefore not further described.

The advantages of this second embodiment are identical to those of the first embodiment and are therefore not further described.

According to another embodiment, the substrate 16 is an amorphous substrate of glass or quartz type.

According to another embodiment, the substrate 16 is a metal substrate.

According to another embodiment, the substrate 16 is a flexible substrate of polymer type.

According to another embodiment, the source 4 and drain 6 electrodes are formed in a superconducting material.

According to another embodiment, the source 4 and drain 6 electrodes are formed in a doped semiconductor material.

According to another embodiment, the superconducting channel 12 is a finned channel.

According to another embodiment, the superconducting material of the channel 12 is aluminium (Al), lead-indium (PbIn), niobium-titanium (NbTi), niobium-tin (NbSn), or magnesium diboride (MgB₂).

It can therefore be understood that the superconductor transistor of the invention provides control over the passing of currents of strong intensity through the superconducting channel thereof, since the density of the free carriers in the superconducting channel is not affected by the field effect which acts solely on the layer of semiconductor material.

It can also be understood that the superconductor transistor of the invention allows amplification of the current in the channel with major gain, through the substantial variation in channel resistance under the field effect, due to polarisation of the gate electrode.

1. Field-effect superconductor transistor comprising a source electrode and a drain electrode, connected by a superconducting channel, the channel and the source and drain electrodes being arranged on a substrate, and a gate electrode covering the channel, wherein it comprises a layer of semiconductor material arranged between the channel and the gate electrode, so as to allow control over the critical current of the superconducting channel by controlling the surface roughness of said channel, said surface roughness being controlled by combining the proximity effect between the superconducting channel and the layer of semiconductor material, with the field effect in the layer of semiconductor material by polarising the gate electrode, said critical current being controlled between a minimum value Ic_min by reducing the surface roughness under the effect of an accumulation of semiconductor free carriers at the interface between the semiconductor layer and the channel with a first polarising voltage of the gate electrode, and a maximum value Ic_max by increasing the surface roughness under the effect of depletion of semiconductor free carriers at the interface between the semiconductor layer and the channel with a second polarising voltage of the gate electrode.

2. The transistor according to claim 1, wherein the gate electrode is galvanically insulated from the channel by an insulating layer arranged on the layer of semiconductor material and in that the transistor is a MOSFET transistor.

3. The transistor according to claim 1, wherein the transistor is a JFET transistor.

4. The transistor according to claim 1, wherein the substrate is a semiconductor substrate.

5. The transistor according to claim 1, wherein the substrate is an amorphous substrate of glass or quartz type.

6. The transistor according to claim 1, wherein the substrate is a metal substrate.

7. The transistor according to claim 1, wherein the substrate is a flexible substrate of polymer type.

8. The transistor according to claim 1, wherein the superconducting channel is in a material from the group consisting of: niobium, aluminium, lead-indium, niobium-titanium, niobium-tin and magnesium diboride.

9. The transistor according to claim 1, wherein the critical current is determined by the width of the superconducting channel, and in that the maximum value Ic_max is equal to or greater than 50 A/cm.

10. The transistor according to claim 1, wherein the critical current is determined by the width of the superconducting channel, and in that the minimum value Ic_min is between 0 A/cm and 0.5 A/cm.

11. The transistor according to claim 1, wherein the thickness of the superconducting channel is between 3 nm and 1 cm.

12. The transistor according to claim 1, wherein the source and drain electrodes are in superconducting material.

13. The transistor according to claim 1, wherein the channel is a finned channel.

14. Method for manufacturing a field-effect superconductor transistor, said transistor comprising a source electrode and a drain electrode, connected by a superconducting channel, the channel and the source and drain electrodes being arranged on a substrate, and a gate electrode covering the channel,
wherein it comprises adding a layer of semiconductor material between the channel and the gate electrode, so as to allow control over the critical current of the superconducting channel by controlling the surface roughness of said channel, said surface roughness being controlled by combining the proximity effect between the superconducting channel and the layer of semiconductor material, with the field effect in the layer of semiconductor material by polarising the gate electrode between a minimum value Ic_min by reducing the surface roughness under the effect of an accumulation of semiconductor free carriers at the interface between the layer of semiconductor and the channel, and a maximum value Ic_max par by increasing the surface roughness under the effect of depletion of semiconductor free carriers at the interface between semiconductor layer and the channel.

15. The method according to claim 14, wherein it comprises adding an insulating layer between the gate electrode and the layer of semiconductor material.

16. The method according to claim 14, wherein the thickness of the superconducting channel is between 3 nm and 1 cm.

17. The method according to claim 14, wherein it comprises forming the substrate in a semiconductor material.

18. The method according to claim 14, wherein it comprises forming the substrate in an amorphous material of glass or quartz type.

19. The method according to claim 14, wherein it comprises forming the substrate in a metal or metal alloy.

20. The method according to claim 14, wherein it comprises forming the substrate in a flexible material of polymer type.

21. The method according to claim 14, wherein it comprises choosing the material of the superconducting channel in the group consisting of: niobium, aluminium, lead-indium, niobium-titanium, niobium-tin and magnesium diboride.

22. The method according to claim 14, wherein it comprises manufacturing the channel in the form of a finned channel.
